(19) United States
(12) Patent Application Publication
(10) Pub. No.: US 2011/0306208 A1
(43) Pub. Date: Dec. 15, 2011

(54) Method for Fabricating Semiconductor Device

(76) Inventors: Jung-Won Lee, Gunpo-si (KR); Dae-Hyuk Kang, Hwaseong-si (KR); Bo-Un Yoon, Seoul (KR); Kun-Tack Lee, Suwon-si (KR)

(21) Appl. No.: 13/157,393

(22) Filed: Jun. 10, 2011

(30) Foreign Application Priority Data
Jun. 11, 2010 (KR) 10-2010-0055690

(51) Int. Cl. H01L 21/28

(52) U.S. Cl. 438/675; 257/E21.158

(57) ABSTRACT

Methods for forming a mold for a storage electrode in a semiconductor device include forming an interlayer dielectric layer including a contact plug on a substrate. A first mold dielectric layer is formed of a first material on the interlayer dielectric layer. A second mold dielectric layer is formed of a second material on the first mold dielectric layer. The second material has a different etch selectivity than the first material. A first opening is formed that penetrates the first and second mold dielectric layers. The first opening is dry etched to define a second opening having a larger width in the first mold dielectric layer than in the second mold dielectric layer based on the different etch selectivity of the first and second mold dielectric layers to define the mold for the storage electrode.

### REFERENCE TO PRIORITY APPLICATION

This application claims priority from Korean Patent Application No. 10-2010-0055690, filed on Jun. 11, 2010 in the Korean Intellectual Property Office, the disclosure of which is incorporated herein by reference in its entirety.

### BACKGROUND

As the density of semiconductor devices is increased, different ways to form a capacitor that may have an increased capacitance have been considered. For example, methods of forming a capacitor have been researched including using various structures or materials in foaming the capacitor. As a result of such research, for example, cylinder or trench type capacitors have been used in semiconductor devices.

The present invention relates to a fabricating method of a semiconductor device, and more particularly, to a fabricating method of a capacitor of a semiconductor device.

### SUMMARY

Embodiments of methods for forming a mold for a storage electrode in a semiconductor device include forming an interlayer dielectric layer including a contact plug on a substrate. A first mold dielectric layer is formed of a first material on the interlayer dielectric layer. A second mold dielectric layer is formed of a second material on the first mold dielectric layer. The second material has a different etch selectivity than the first material. the second mold dielectric layer and the first mold dielectric layer are selectively etched in sequence to form a first opening. The first opening is dry etched to define a second opening having an increased width in the first mold dielectric layer relative to that in the second mold dielectric layer based on the different etch selectivity of the first and second mold dielectric layers to define the mold for the storage electrode.

In other embodiments, forming the second mold dielectric layer includes sequentially stacking the second mold dielectric layer directly on the first mold dielectric layer. Forming the first dielectric mold layer may be preceded by forming an etch stop layer on the interlayer dielectric layer and forming the first mold dielectric layer may include forming the first mold dielectric layer on the etch stop layer. A storage electrode may be conformally formed in the second opening. Forming the storage electrode may be preceded by selectively etching the etch stop layer to align the second opening and expose the contact plug. Dry etching the first opening may be performed before selectively etching the etch stop layer to limit etching of a bottom of the first opening during dry etching of the first opening.

In further embodiments, dry etching the first opening includes selectively expanding sidewalls of the first opening in the first mold dielectric layer while the sidewalls of the first opening in the second mold dielectric layer are substantially unchanged. The first mold dielectric layer may be a dielectric layer doped with impurities and the second mold dielectric layer may be a dielectric layer without impurity doping.

In other embodiments, the first mold dielectric layer is a Boron Phosphorus Silicate Glass (BSPG) layer and the second mold dielectric layer is a Tetra Ethyl Ortho Silicate (TEOS) layer. The first mold dielectric layer may be a Boron Phosphorus Silicate Glass (BSPG) layer or a Phosphorus Silicate Glass (PSG) layer and the second mold dielectric layer may be a Tetra Ethyl Ortho Silicate (TEOS) layer or a High Density Plasma (HDP) oxide layer or a P—SiH4 oxide layer. Dry etching the first opening may include dry etching the first opening using a Buffer Oxide Etchant (BOE) solution including fluoric acid or an HF/NH4F mixture as an etchant. Dry etching the first opening may include performing a chemical oxide removal (COR) process.

In further embodiments, selectively etching the second and first mold dielectric layers is preceded by forming a third mold dielectric layer including a sequentially stacked support layer and a lightly doped dielectric layer on the second mold dielectric layer and selectively etching the support layer and a lightly doped dielectric layer to form the first opening. The storage electrode may be the lower electrode of a capacitor.

In yet other embodiments, a method of forming a semiconductor device includes forming an interlayer dielectric layer including a contact plug on a substrate. A first mold dielectric layer doped with impurities is formed on the interlayer dielectric layer. A second mold dielectric layer without doped impurities is formed on the first mold dielectric layer. An opening is formed that penetrates the first mold dielectric layer and the second mold dielectric layer. A chemical oxide removal process is performed on the semiconductor device including the opening to selectively expand sidewalls of the opening in the first mold dielectric layer while maintaining the sidewalls of the opening in the second mold dielectric layer substantially unchanged to define a mold for a storage electrode. A storage electrode is formed along the mold for the storage electrode and contacting the contact plug.

In other embodiments, forming the first mold dielectric layer is preceded by forming an etch stop layer on the interlayer dielectric layer and forming the first mold dielectric layer includes forming the first mold dielectric layer on the etch stop layer and forming the storage electrode is preceded by selectively etching the etch stop layer to expose the contact plug.

### BRIEF DESCRIPTION OF THE DRAWINGS

The above and other features and advantages of the present invention will become apparent by describing in detail exemplary embodiments thereof with reference to the attached drawings in which:

FIGS. 1 through 6 are sectional views illustrating a method of forming a semiconductor device according to some embodiments of the present invention; and

FIG. 7 is a graph illustrating etch rate of BPSG and TEOS for chemical oxide removal processes according to some embodiments of the present invention.

### DETAILED DESCRIPTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

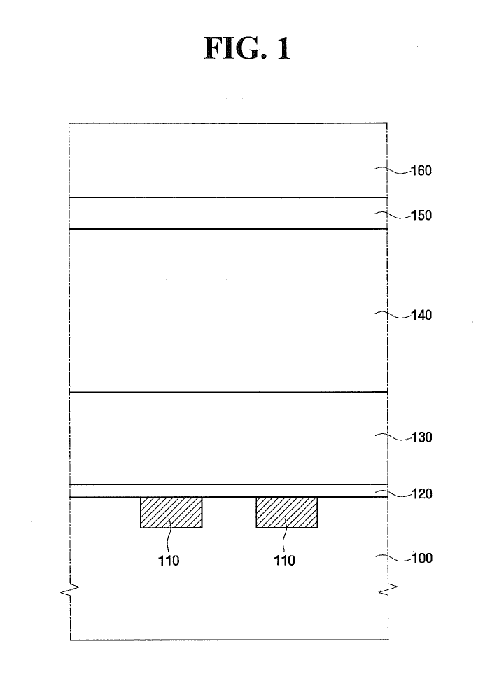

Hereinafter, referring to FIGS. 1 through 6, a method of forming a semiconductor device according to some embodiments of the present invention will be described.

First, referring to FIG. 1, on a substrate (not shown) an interlayer dielectric layer 100 including a contact plug 110 is formed. The substrate may be, for example, a substrate composed of at least one material selected from the group consisting of Si, Ge, SiGe, GaP, GaAs, SiC, SiGeC, InAs, and InP, or a SOI (Silicon On Insulator) substrate can be used. Other substrate types may be used in some embodiments. The process to form the interlayer dielectric layer 100 and the contact plug(s) 110 on the substrate can be performed, for example, using conventional methods. It will be understood that, in some embodiments, various active devices, passive devices and/or interconnections may be formed under the contact plug 110.

Next, on the interlayer dielectric layer 100 a first mold dielectric layer 130 and a second mold dielectric layer 140 are formed in a sequentially stacked relationship. The mold dielectric layers 130, 140 are formed of different materials.

More specifically, the first mold dielectric layer 130 can be a dielectric layer doped with impurities, and the second mold dielectric layer 140 can be a dielectric layer without impurity doping (or substantially free of the impurities doped in the first mold dielectric layer 130). For example, the first mold dielectric layer 130 may be BPSG (Boron Phosphorus Silicate Glass) or PSG (Phosphorus Silicate Glass); however, it is not limited thereto. The second mold dielectric layer 140 without impurity doping may be PE-TEOS (Plasma Enhanced Tetra Ethyl Ortho Silicate), a HDP (High Density Plasma) oxide layer, or a P—SiH4 oxide layer; however, it is not limited thereto.

Before sequentially stacking the first mold dielectric layer 130 and the second mold dielectric layer 140, an etch stop layer 120 may be formed. Thus, as illustrated in FIG. 1, the interlayer dielectric layer 100 including the contact plug 110, the etch stop layer 120, the first mold dielectric layer 130, and the second mold dielectric layer 140 may be stacked sequentially. Also shown stacked on this structure in FIG. 1 are third mold dielectric layers 150, 160.

The etch stop layer 120 may be configured to limit depth of etching in the subsequent process that will be described below related to etching the mold dielectric layers 130, 140, 150, and 160. Also, the mold dielectric layers 130, 140, 150, and 160 may be formed using materials having different etch selectivity. For example, when the mold dielectric layers 130, 140, 150, and 160 are silicon oxide layers, the etch stop layer 120 may be formed as a silicon nitride layer.

As noted above, on the second mold dielectric layer 140 at least one of the third mold dielectric layers 150 and 160 may be formed. As illustrated in FIG. 1, the third mold dielectric layers 150 and 160 can include more than one multiple layers. For example, the third mold dielectric layers 150 and 160 may include a support unit 150 and a lightly doped dielectric layer 160. The etch stop layer 120 and the mold dielectric layers 130, 140, 150, and 160 can be formed, for example, using chemical vapor deposition (CVD) equipment by a CVD process.

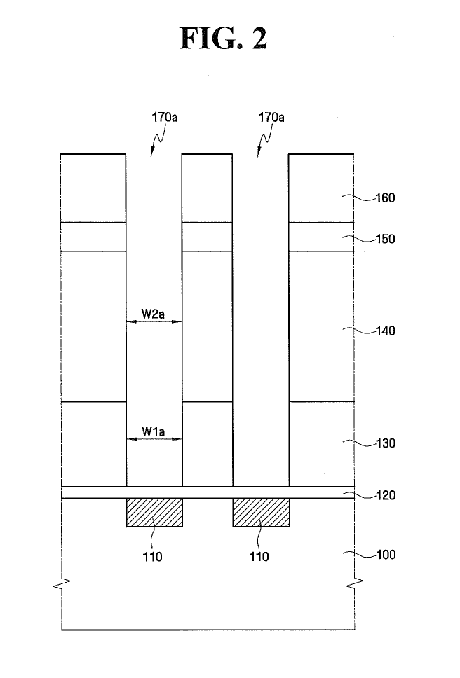

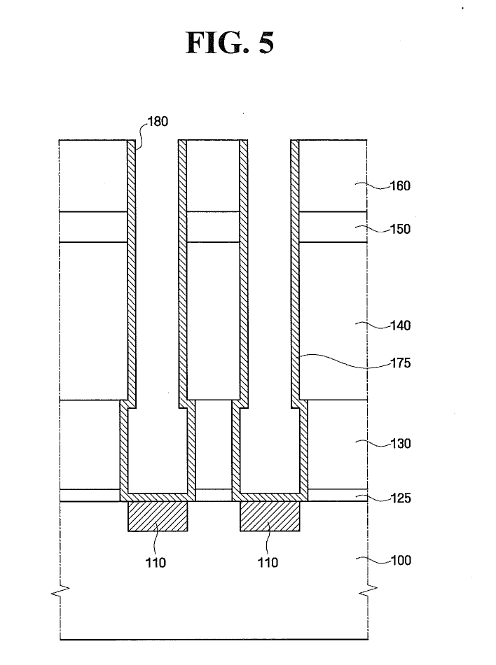

Referring to FIG. 2, a first opening 170a that penetrates the first mold dielectric layer 130 and the second mold dielectric layer 140 is formed. The first opening 170a may be formed by selectively etching the second mold dielectric layer 140 and the first mold dielectric layer 130 in sequence. In some embodiments, by forming the first opening 170a that sequentially penetrates the first mold dielectric layer 130 and the second mold dielectric layer 140, a reserve mold for a storage electrode 180 (FIG. 5) may be formed. The first opening 170a can be formed, for example, by photo lithograpy. For example, on the mold dielectric layers 130, 140, 150, and 160, a photoresist solution is spread, and exposure and development process are performed to form photoresist patterns that define the first opening 170a. Then, using the photoresist patterns as an etch mask, the second mold dielectric layer 140 and the first mold dielectric layer 130 are sequentially etched to form the first opening 170a therein.

As described earlier, when the third mold dielectric layers 150 and 160 are formed on the second mold dielectric layer 140, the third mold dielectric layers 150 and 160, as well as the second mold dielectric layer 140, and the first mold dielectric layer 130, may be sequentially etched to form the first opening 170a.

When the width of the first opening 170a in the first mold dielectric layer 130 is defined as a first width W1a and the width of the first opening 170a in the second mold dielectric layer 140 is defined as a second width W2a, as illustrated in FIG. 2, the sizes of the first width W1a defined in a lower region and the second width W2a defined an upper region of the first opening 170a can be substantially identical.

However, although not illustrated in FIG. 2, in other exemplary embodiments the first opening 170a can have a sidewall profile such that the sidewall is expanded due, for example, to etch gas and bowing phenomenon. Such bowing phenomenon can mean a phenomenon where an aspect ratio of the opening is increased as the depths (thicknesses) of the mold dielectric layers 130, 140, 150, and 160 are increased. As a result, the upper region of the opening 170a may be relatively (to lower region) expanded due, for example, to reflection or diffusion of the etch gases during etch process to form the opening. In other exemplary embodiments, the second width W2a defined in the upper region of the first opening 170a can be formed to be larger than the first width W1a defined in the lower region of the first opening 170a.

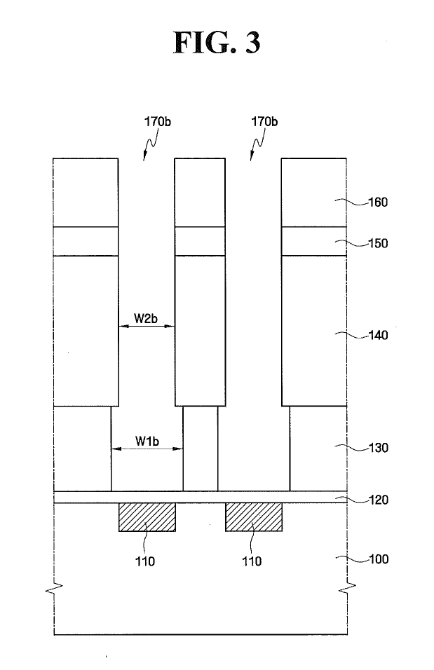

Referring now to FIG. 3, by performing dry etch process, a second opening 170b where sidewalls of the first mold dielectric layer 130 of the first opening (170a of FIG. 2) are selectively expanded is formed. During the dry etching process, the width (diameter) of the sidewalls formed in the second mold dielectric layer 140 of the first opening 170a are maintained while the width of the sidewalls in the first mold dielectric layer 130 can be narrowed by selectively removing portions of the sidewalls in the first mold dielectric layer 130. As a result, as illustrated in FIG. 3, a width Wlb in the sidewalls in the first mold dielectric layer 130 of the second opening 170b can be larger than a width W2b in the sidewalls in the second mold dielectric layer 140.

Thus, in the dry etch process used above, by using an etch gas having higher etch selectivity of the first mold dielectric layer 130 over the second mold dielectric layer 140, the sidewalls in the region of the first mold dielectric layer 130 of the first opening 170a can be selectively etched to expand the width of the opening to define the second opening 170b (i.e., the second opening 170b corresponds to the first opening 170a after further selective etching of the first opening 170a in the layer 130).

When performing the dry etch process, a Chemical Oxide Removal (COR) process can be used. By adjusting the chemical oxide removal with the COR process, the first mold dielectric layer 130 can be selectively removed. As a result, as described earlier, the second opening 170b where the width Wlb of the sidewalls in the first mold dielectric layer 130 is larger than the width W2b of the sidewalls in the second mold dielectric layer 140 can be formed. The chemical oxide removal (COR) process can be a dry etch process that does not use water to remove an oxide layer. In other exemplary embodiments, the chemical oxide removal (COR) process does not use plasma, and can provide isotropic etch characteristics like a wet etch.

When using a dry etching process to selectively expand the sidewalls of the first opening 170a in a lower region where the first mold dielectric layer 130 is formed, the lower region may be expanded with little or no expansion in the upper region of the first opening 170a where the second mold dielectric layer 140 is formed. As such, a desired threshold of the lower region of the first opening 170a can be obtained. Also, by expanding (enlarging) the lower region of the opening 170a, the width of the lower region in the opening 170b can be increased. As a result, the resistance between contacts associated therewith can be reduced and a leaning phenomenon can be improved.

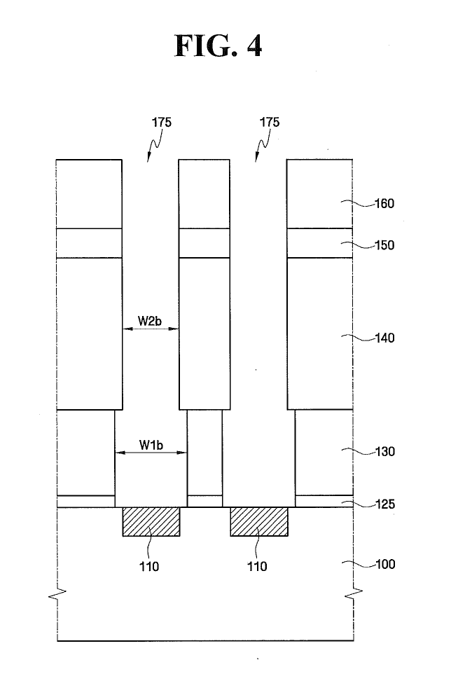

Next, referring to FIG. 4, the etch stop layer (refer to 120 of FIG. 3) can be selectively etched to be aligned with the second opening 170b to expose the contact plug 110. Thus, an etch stop layer pattern 125 that exposes the contact plug 110 to be aligned with the second opening 170b can be formed. As a result, the mold opening 175 for forming the storage electrode can be defined. In other words, the mold for forming the storage electrode is defined by the layers 130, 140, 150, 160 with the opening(s) 175 therein.

By forming the second opening 170b having a larger lower region width Wlb, the threshold of a lower region of the mold opening 175 for the storage electrode can be obtained. Also, the width of the lower region of the mold opening 175 for the storage electrode is defined is increased, and as a result the resistance between contacts can be reduced and the leaning phenomenon can be improved.

Next, referring to FIG. 5, along the second opening 170b, for example the inside walls of the mold opening 175 for storage electrode, a storage electrode 180 is formed.

Although not shown in the drawing, a storage electrode conductive layer can be conformally formed along the inside of the second opening 170b. The storage electrode conductive layer can have contact with a top of the exposed contact plug 110. The storage electrode conductive layer, for example, can be composed of a single layer or a multi-layer of Ru, Ir, Ti, TiN, or conductive polysilicon; however, it is not limited thereto and it can be formed by conventional deposition methods including chemical vapor deposition (CVD), atomic layer deposition (ALD) and/or physical vapor deposition (PVD).

A remaining space inside of the second opening 170b having the storage electrode conductive layer fanned therein is filled with a material to be used for the storage electrode 180. By forming a sacrificial capping layer (not shown) having a higher top surface than the mold opening 175 for the storage electrode and planarizing the sacrificial capping layer and the storage electrode conductive layer, the node-isolated storage electrode 180 can be formed. In this step, for the sacrificial capping layer, a dielectric layer having superior gap filling characteristics, for example, oxide layer materials including BPSG (borophosphosilicate glass), PSG (phosilicate glass), USG (Undoped Silicate Glass), ALD (Atomic Layer Deposition) oxide can be used; however, it is not limited thereto.

Furthermore, the planarization process can be performed by a chemical mechanical process (CMP) or a dry etch back process. As a result, the top of the mold opening 175 for the storage electrode can be exposed.

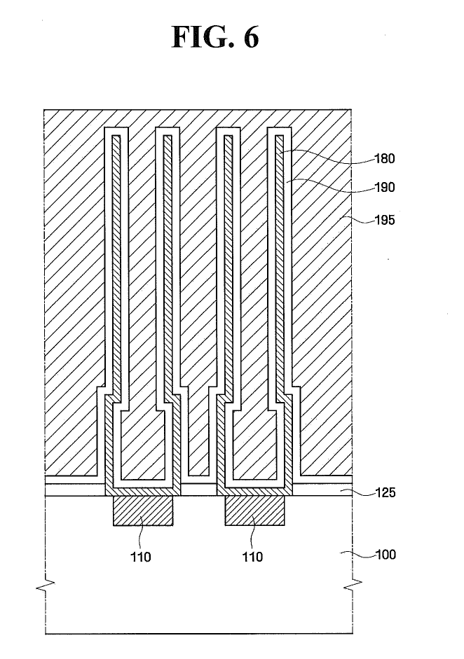

Referring to FIG. 6, the layers 130, 140, 150, 160 defining the mold opening 175 for the storage electrode and the sacrificial capping layer are removed. A dielectric layer 190 and an upper electrode 195 are sequentially formed on the storage electrode 180 to form a capacitor. The process to form the dielectric layer 190 and the upper electrode 195 may be, for example, CVD, ALD, or PVD.

More specifically, the layers 130, 140, 150, 160 and the sacrificial capping layer may be removed, for example, using a wet etch process. For example, they can be etched using BOE (Buffer Oxide Etchant) solution including fluoric acid or HF/NH4F mixture; however, it is not limited thereto. After such a wet removal process a conventional dry process can be performed. In other exemplary embodiments, the layers 130, 140, 150, 160 and the sacrificial capping layer can be removed sequentially or simultaneously using a dry etch process.

The dielectric layer 190 can be formed, for example, with a single layer of tantalum oxide (Ta2O5) layer or aluminum oxide (Al2O3) layer or with a stacked layer of a tantalum oxide layer/a titanium oxide layer or an aluminum oxide layer/a titanium oxide layer; however, it is not limited thereto. Also, the upper electrode 195 can be formed with a same conductive material as the storage electrode 180, or it can be formed with different material.

Then, according to the process steps that are widely known to those skilled in the art, operations to form interconnections, operations to form a passivation layer on the substrate, and operations to package the substrate may be performed to complete the semiconductor device. To avoid ambiguous interpretation of the present invention, exemplary subsequent steps are described generally herein.

Although the present invention has been described in connection with the exemplary embodiments of the present invention with reference to the accompanying drawings, it will be apparent to those skilled in the art that various modifications and changes may be made thereto without departing from the scope and spirit of the invention. Therefore, it should be understood that the above embodiments are not limitative, but illustrative in all aspects.

More details about the present invention are described using the following specific experimental examples. Since the contents not described here will be understood by those skilled in the art in light of this specification, the descriptions will not include all details of the operations described in the examples.

### Experimental Example

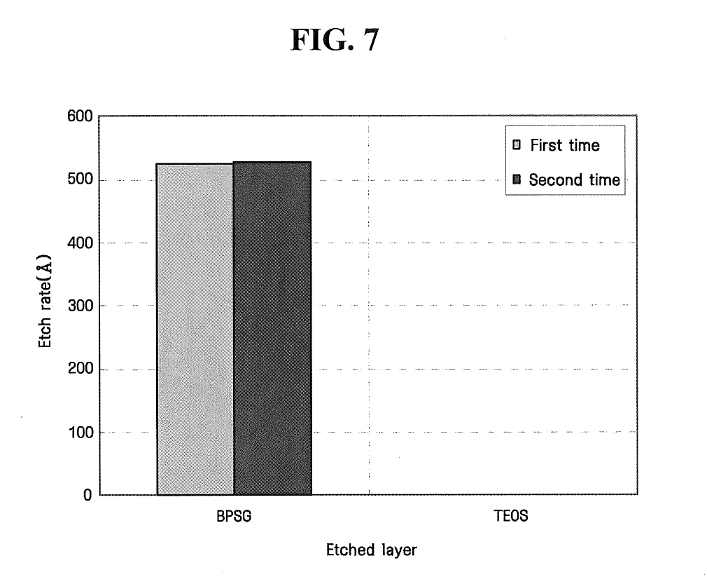

An exemplary experiment will be used to identify etch rate of the first and second mold dielectric layers applied to embodiments of the present invention. More specifically, a BPSG layer and a TEOS layer are formed as etched layers, and a chemical oxide removal process is performed. The process is performed to etch only the BPSG layer selectively. Thus, using an etch solution not including NH3 and only including HF under the condition of a high temperature under approximately 60° C. and a high pressure under approximately 1,000 milliTorres (mT), the chemical oxide removal process is performed twice on the BPSG layer and the TEOS layer and the results are shown in FIG. 7.

As shown in FIG. 7, in case where the etched layer was the BPSG layer the etch rate of the etched layer is above 500 Å for the two oxide removal processes. However, it is shown that, in the case where the etched layer is the TEOS layer, the etch rate of the etched layer is close to 0 Å for the two oxide removal processes. Therefore, even though the etched layer includes the BPSG layer and the TEOS layer, it is observed that the BPSG layer is selectively removed.

Typically, since anhydrous HF alone cannot remove an oxide layer under the condition with no moisture, TEOS is not etched by the etch process only including fluoric acid. However, as an oxide layer doped with impurities, such as BPSG, has a relatively higher hydroscopicity in the atmosphere than that of an oxide layer without impurity doping, on a surface of the BPSG layer a layer that contains moisture in the atmosphere can be formed. As a result, with anhydrous HF alone the oxide layer may be removed.

Therefore, according to a fabricating (forming) method of a semiconductor device based on the exemplary embodiments of the present invention, when a mold for a storage electrode is defined by forming an opening inside the mold dielectric layer(s), by forming the first mold dielectric layer placed on a lower region of the mold dielectric layer as the BPSG layer and forming the second mold dielectric layer placed on an upper region of the mold dielectric layer as the TEOS layer the width of the lower region of the opening formed in the mold can be selectively expanded.

Due to the miniaturization and high integration trends of semiconductor devices, aspect ratios are typically increased. As a result, the contact area between a capacitor and a lower plug may be decreased, and it may be difficult to form a capacitor electrode stably. Some embodiments of the present invention provide a fabricating method of a semiconductor device with improved reliability. However, the aspects, features and advantages of the present invention are not restricted to the ones set forth herein. The above and other aspects, features and advantages of the present invention will become more apparent to one of ordinary skill in the art to which the present invention pertains by referencing the detailed description of the present invention given herein.

In some embodiments of the present invention, there is provided a method of fabricating a semiconductor device, which includes forming an interlayer dielectric layer including a contact plug on a substrate; sequentially stacking a first mold dielectric layer and a second mold dielectric layer including different materials with the first mold dielectric layer on the interlayer dielectric layer; forming a first opening that penetrates the first mold dielectric layer and the second mold dielectric layer; performing a dry etch to form a second opening forming where sidewalls of the first mold dielectric layer of the first opening are selectively expanded; and forming a storage electrode along inside walls of the second opening.

In other embodiments of the present invention, there is provided a method of fabricating a semiconductor device, which includes forming an interlayer dielectric layer including a contact plug on a substrate; sequentially stacking a first mold dielectric layer doped with impurities and a second mold dielectric layer without doping impurity; forming an opening that penetrates the first mold dielectric layer and the second mold dielectric layer to form a reserve mold for storage electrode; performing a chemical oxide removal process to form a mold for storage electrode where sidewalls in the second mold dielectric layer are maintained and sidewalls in the first mold dielectric layer are selectively removed; and forming a storage electrode along the mold for storage electrode.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method for forming a mold for a storage electrode in a semiconductor device, the method comprising:
forming an interlayer dielectric layer including a contact plug on a substrate;
forming a first mold dielectric layer of a first material on the interlayer dielectric layer;
forming a second mold dielectric layer of a second material on the first mold dielectric layer, wherein the second material has a different etch selectivity than the first material;
selectively etching the second mold dielectric layer and the first mold dielectric layer in sequence to form a first opening therein; and
dry etching the first opening to define a second opening having an increased width in the first mold dielectric layer relative to that in the second mold dielectric layer based on the different etch selectivity of the first and second mold dielectric layers to define the mold for the storage electrode.

2. The method of claim 1, wherein forming the second mold dielectric layer comprises sequentially stacking the second mold dielectric layer directly on the first mold dielectric layer.

3. The method of claim 1, wherein forming the first dielectric mold layer is preceded by forming an etch stop layer on the interlayer dielectric layer and wherein forming the first mold dielectric layer comprises forming the first mold dielectric layer on the etch stop layer.

4. The method of claim 3, further comprising conformally forming the storage electrode in the second opening.

5. The method of claim 4, wherein forming the storage electrode is preceded by selectively etching the etch stop layer to align the second opening and expose the contact plug, wherein dry etching the first opening is performed before selectively etching the etch stop layer to limit etching of a bottom of the first opening during dry etching of the first opening.

6. The method of claim 1, wherein dry etching the first opening includes selectively expanding sidewalls of the first opening in the first mold dielectric layer while the sidewalls of the first opening in the second mold dielectric layer are substantially unchanged.

7. The method of claim 1, wherein the first mold dielectric layer is a dielectric layer doped with impurities and the second mold dielectric layer is a dielectric layer without impurity doping.

8. The method of claim 1, wherein the first mold dielectric layer is a Boron Phosphorus Silicate Glass (BSPG) layer and the second mold dielectric layer is a Tetra Ethyl Ortho Silicate (TEOS) layer.

9. The method of claim 8, wherein the first mold dielectric layer is a Boron Phosphorus Silicate Glass (BSPG) layer or a Phosphorus Silicate Glass (PSG) layer and the second mold dielectric layer is a Tetra Ethyl Ortho Silicate (TEOS) layer or a High Density Plasma (HDP) oxide layer or a P—SiH4 oxide layer and wherein dry etching the first opening comprises dry etching the first opening using a Buffer Oxide Etchant (BOE) solution including fluoric acid or an HF/NH₄F mixture as an etchant.

10. The method of claim 1, wherein dry etching the first opening includes performing a chemical oxide removal (COR) process.

11. The method of claim 1, wherein selectively etching the second mold dielectric layer and the first mold dielectric layer in sequence is preceded by forming a third mold dielectric layer including a sequentially stacked support layer and a lightly doped dielectric layer on the second mold dielectric layer and selectively etching the support layer and a lightly doped dielectric layer to form the first opening.

12. The method of claim 1, wherein the storage electrode comprised the lower electrode of a capacitor.

13. A method of forming a semiconductor device, the method comprising:
forming an interlayer dielectric layer including a contact plug on a substrate;
forming a first mold dielectric layer doped with impurities on the interlayer dielectric layer;
forming a second mold dielectric layer without doped impurities on the first mold dielectric layer;
forming an opening that penetrates the first mold dielectric layer and the second mold dielectric layer;
performing a chemical oxide removal process on the semiconductor device including the opening to selectively expand sidewalls of the opening in the first mold dielectric layer while maintaining the sidewalls of the opening in the second mold dielectric layer substantially unchanged to define a mold for a storage electrode; and
forming a storage electrode along the mold for the storage electrode and contacting the contact plug.

14. The method of claim 13, wherein forming the first mold dielectric layer is preceded by forming an etch stop layer on the interlayer dielectric layer and wherein forming the first mold dielectric layer comprises forming the first mold dielectric layer on the etch stop layer and wherein forming the storage electrode is preceded by selectively etching the etch stop layer to expose the contact plug.

15. The method of claim 13, wherein the first mold dielectric layer is a Boron Phosphorus Silicate Glass (BSPG) layer and the second mold dielectric layer is a Tetra Ethyl Ortho Silicate (TEOS) layer.

16. The method of claim 13, wherein the first mold dielectric layer is a Boron Phosphorus Silicate Glass (BSPG) layer or a Phosphorus Silicate Glass (PSG) layer and the second mold dielectric layer is a Tetra Ethyl Ortho Silicate (TEOS) layer or a High Density Plasma (HDP) oxide layer or a P—SiH4 oxide layer.
